(19) United States
(12) Patent Application Publication
(10) Pub. No.: US 2009/0246954 A1
(43) Pub. Date: Oct. 1, 2009

(54) METHOD OF MANUFACTURING SEMICONDUCTOR DEVICE

(76) Inventors: Seiro Miyoshi, Yokohama-shi (JP); Hidefumi Mukai, Kawasaki-shi (JP); Kazuyuki Masukawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/406,430

(22) Filed: Mar. 18, 2009

(30) Foreign Application Priority Data
Mar. 27, 2008 (JP) 2008-083425

(51) Int. Cl. H01L 21/308

(52) U.S. Cl. 438/689; 257/E21.235

(57) ABSTRACT

A method of manufacturing a semiconductor device, includes forming a plurality of core portions arranged in a predetermined direction, on a to-be-processed film, forming a stacked sidewall portion in which a first sidewall portion and a second sidewall portion are stacked in that order, on each of side surfaces, of each of the core portions, removing the core portions to form a structure having a first space between the adjacent first sidewall portions and a second space between the adjacent second sidewall portions, and retreating at least one of the first sidewall portion and the second sidewall portion by a desired retreat amount to slim the stacked sidewall portion, after removing the core portions.

### CROSS-REFERENCE TO RELATED APPLICATIONS

This application is based upon and claims the benefit of priority from prior Japanese Patent Application No. 2008-083425, filed Mar. 27, 2008, the entire contents of which are incorporated herein by reference.

### BACKGROUND OF THE INVENTION

1. Field of the Invention

This invention relates to a method of manufacturing a semiconductor device.

2. Description of the Related Art

Formation of a fine pattern becomes difficult in accordance with fining of a semiconductor device. To solve this problem, a method of forming sidewall portions on both side surfaces of a core portion, removing the core portion and etching a to-be-processed film with the remaining sidewall portions serving as a mask has been proposed (see, for example, U.S. Pat. No. 5,013,680). By employing this method, a pattern having a half cycle of a pattern of the core pattern can be formed.

In this method, however, for example, positions of the sidewall portions are varied if dimensions of the core portion are varied. For this reason, a pattern of the to-be-processed film as formed with the sidewall portions serving as the etching mask cannot be formed at a desired position at a good accuracy.

### BRIEF SUMMARY OF THE INVENTION

A method of manufacturing a semiconductor device, according to an aspect of the present invention comprises: forming a plurality of core portions arranged in a predetermined direction, on a to-be-processed film; forming a stacked sidewall portion in which a first sidewall portion and a second sidewall portion are stacked in that order, on each of side surfaces, of each of the core portions; removing the core portions to form a structure having a first space between the adjacent first sidewall portions and a second space between the adjacent second sidewall portions; and retreating at least one of the first sidewall portion and the second sidewall portion by a desired retreat amount to slim the stacked sidewall portion, after removing the core portions.

### BRIEF DESCRIPTION OF THE SEVERAL VIEWS OF THE DRAWING

FIG. 1 to FIG. 10 are cross-sectional views illustrating a method of manufacturing a semiconductor device according to an embodiment of the present invention; and

FIG. 11 to FIG. 13 are cross-sectional views illustrating a method of manufacturing a semiconductor device according to a comparative example of the embodiment of the present invention.

### DETAILED DESCRIPTION OF THE INVENTION

Embodiments of the present invention will be explained below with reference to the accompanying drawings.

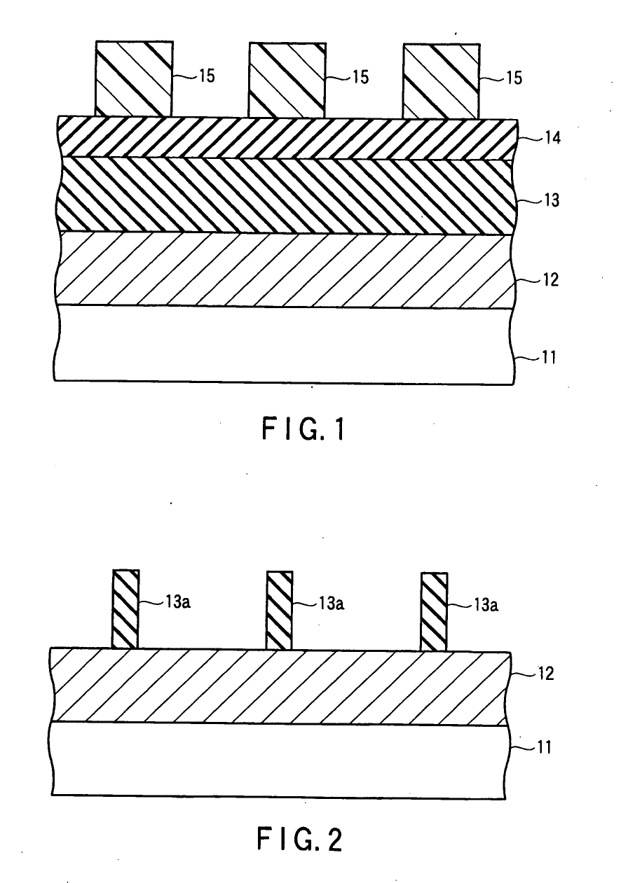

FIG. 1 to FIG. 10 are cross-sectional views illustrating a method of manufacturing a semiconductor device according to an embodiment of the present invention.

In a step of FIG. 1, first, a polysilicon film having a thickness of approximately 200 nm is formed as a to-be-processed film 12, on a substrate 11 including a semiconductor substrate. Then, a carbon film having a thickness of approximately 200 nm is formed as a core film 13, on the to-be-processed film 12, by CVD. Further, an SOG film having a thickness of approximately 50 nm is formed as an anti-reflection coating 14, on the core film 13.

Next, a photoresist is applied onto the anti-reflection coating 14 and baked at 90° C. for 60 seconds to form a photoresist film having a thickness of approximately 130 nm. A topcoat material is applied onto the photoresist film. The topcoat material is baked at 90° C. for 60 seconds to form a topcoat film having a thickness of approximately 90 nm.

Next, a pattern formed on a photomask is transferred onto the photoresist film by an exposure device. The numerical aperture (NA) of the exposure device is 1.0 and the exposure light thereof is ArF light (wavelength: 193.3 nm). After the exposure, baking is executed at 115° C. for 60 seconds. After that, development is executed with a 2.38% solution of tetramethylammonium hydroxide (TMAH) and rinsing is further executed with pure water. As a result, a photoresist pattern 15 having a thickness of approximately 120 nm is formed. As the photoresist pattern 15, a line-and-space pattern (pitch: 120 nm, line width: 60 nm) is formed. The topcoat material is not shown in FIG. 1 since the topcoat material is dissolved in the developer.

In a step of FIG. 2, photoresist pattern 15 is subjected to slimming by a method such as ashing to narrow the width of the photoresist pattern 15. Then, the anti-reflection coating 14 and the core film 13 are etched with the slimmed photoresist pattern 15 serving as a mask. Further, the photoresist pattern 15 and the anti-reflection coating 14 are removed. A plurality of core portions 13a aligned in the same pitch along a predetermined direction are thereby formed on the to-be-processed film 12.

The step of FIG. 2 can be modified in the following manners. First, the anti-reflection coating 14 and the core film 13 are etched with the photoresist pattern 15 (which may be slimmed or not) serving as a mask. Further, a preliminary core portion is obtained by removing the photoresist pattern 15 and the anti-reflection coating 14. Then, the core portions 13a are formed by slimming the preliminary core portion.

A width of the core portions 13a formed in the step of FIG. 2 is often smaller than a space width (for example, 30 nm) of the finally obtained line-and-space pattern (pitch: 60 nm).

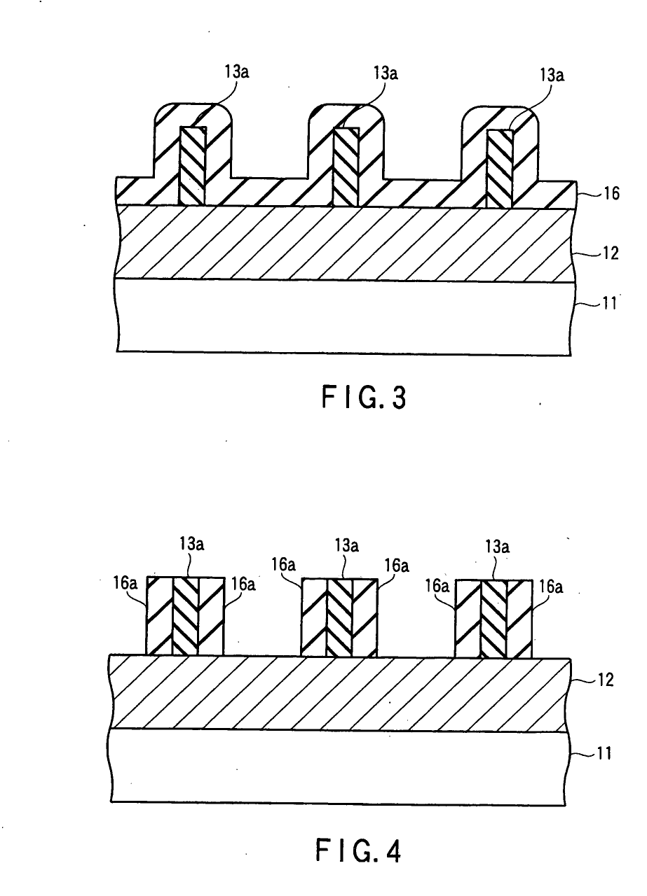

In a step of FIG. 3, a silicon oxide film is formed on an entire surface as a sidewall material film (first sidewall material film) 16, and the to-be-processed film 12 and the core portions 13a are covered with the sidewall material film 16.

In a step of FIG. 4, the sidewall material film 16 is etched by anisotropic etching. As a result, sidewall portions (first sidewall portions) 16a are formed on both side surfaces of the core portions 13a.

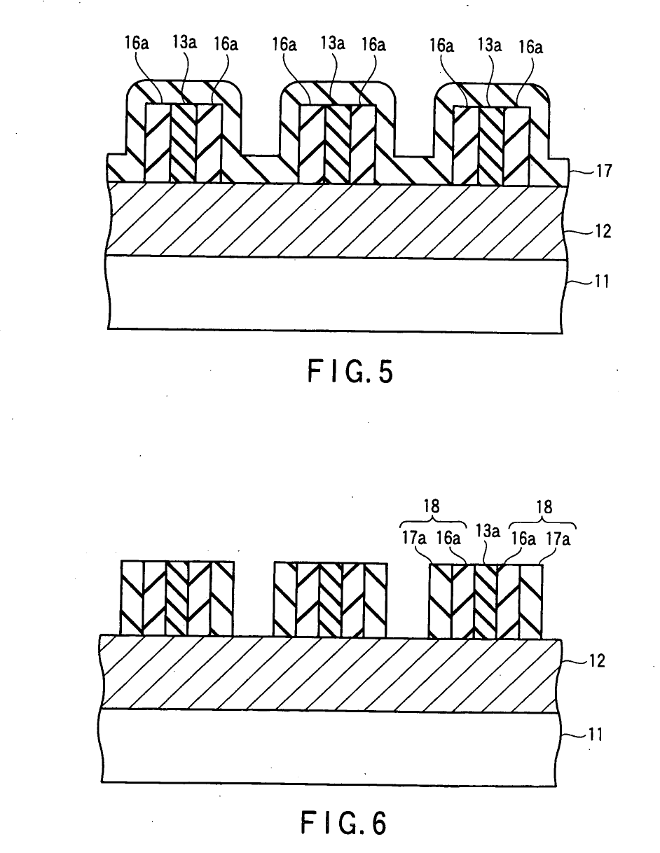

In a step of FIG. 5, a silicon nitride film is formed on an entire surface as a sidewall material film (second sidewall material film) 17, and the to-be-processed film 12, the core portions 13a and the sidewall portions 16a are covered with the sidewall material film 17.

In a step of FIG. 6, the sidewall material film 17 is etched by anisotropic etching. As a result, a stacked sidewall portion 18 in which the sidewall portion (first sidewall portion) 16a and a sidewall portion (second sidewall portion) 17a are stacked is formed on each of both the side surfaces, of each of core portions 13a. In other words, the sidewall portions 17a are formed on both the side surfaces of the core portions 13a with the sidewall portions 16a interposed therebetween. A space width between adjacent sidewall portions 17a is often smaller than the space width (for example, 30 nm) of the finally obtained line-and-space pattern (pitch: 60 nm).

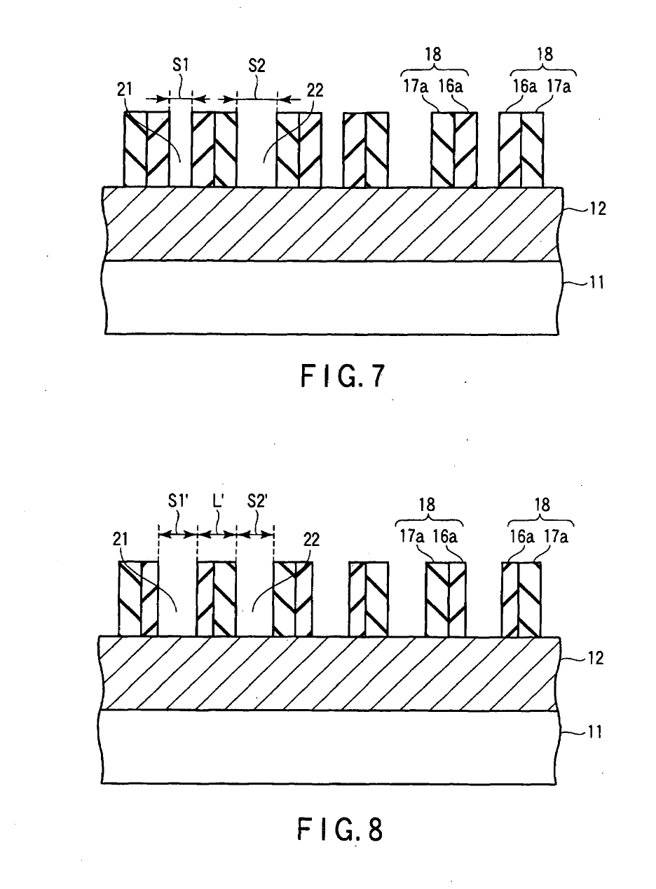

In a step of FIG. 7, the core portions 13a formed of the carbon film are removed by ashing using oxygen. As a result, a space (first space) 21 is formed between the sidewall portions 16a which are adjacent without sandwiching the sidewall portions 17a and a space (second space) 22 is formed between the sidewall portions 17a which are adjacent without sandwiching the sidewall portions 16a.

Next, positions of the sidewall portions 16a and the sidewall portions 17a are measured by an electron microscope (for example, CD-SEM). In this measurement, for example, a space width S1 of the space 21 and a space width S2 of the space 22 are measured.

In a step of FIG. 8, the sidewall portions 16a and the sidewall portions 17a are retreated by desired retreat amounts, respectively, on the basis of the measurement result, to slim the stacked sidewall portions 18. In other words, if the space width S1 of the space 21 obtained in the step of FIG. 7 is smaller than the space width S2 of the space 22, slimming control is executed such that the retreat amount of the sidewall portions 16a is greater than the retreat amount of the sidewall portions 17a. Oppositely, if the space width S2 of the space 22 is smaller than the space width S1 of the space 21, slimming control is executed such that the retreat amount of the sidewall portions 17a is greater than the retreat amount of the sidewall portions 16a. As a result, a space width S1′ of the space 21 becomes equal to a space width S2′ of the space 22. In the present embodiment, a line width L′ of the stacked sidewall portions 18 is also equal to the space widths S1′ and S2′.

The above-described slimming of the stacked sidewall portions 18 is executed by plasma etching using a mixture gas of C₄F₈ gas and CO gas. For example, if a flow rate of C₄F₈ gas and CO gas (C₄F₈/CO) is increased, a ratio between an etching rate (E2) of the silicon nitride film and an etching rate (E1) of the silicon oxide film (E2/E1) can be increased. Oppositely, if the flow rate (C₄F₈/CO) is decreased, the ratio (E2/E1) can be decreased. Therefore, the retreat amount of the sidewall portions 16a formed of the silicon oxide film and the retreat amount of the sidewall portions 17a formed of the silicon nitride film can be adjusted by adjusting the flow rate (C₄F₈/CO).

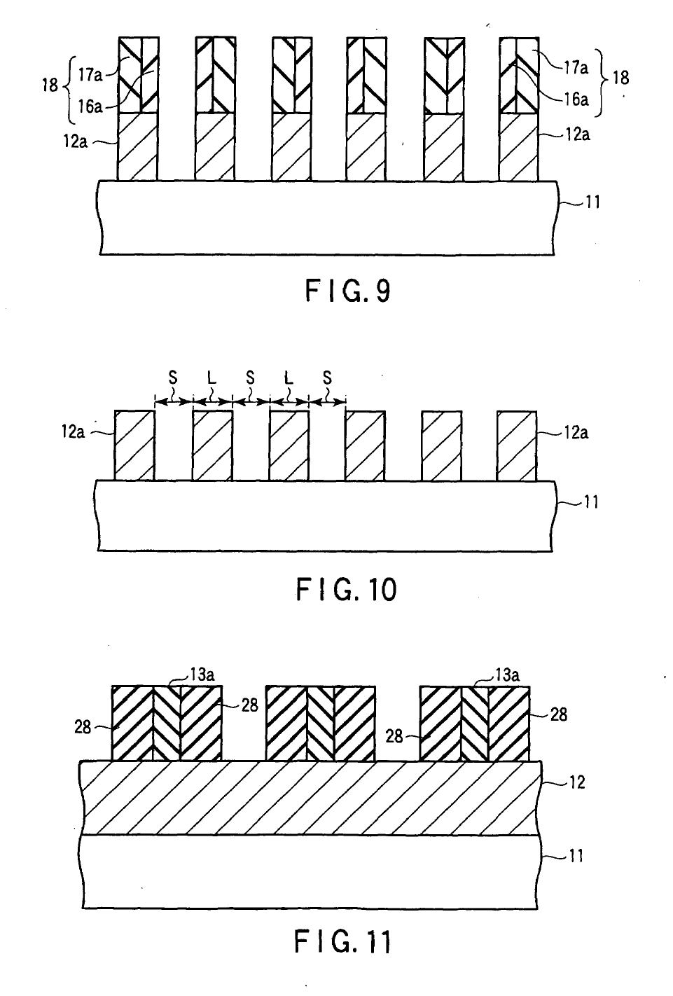

In a step of FIG. 9, the to-be-processed film 12 is etched with the slimmed stacked sidewall portions 18 serving as a mask to form a to-be-processed film pattern 12a. More specifically, the to-be-processed film (polysilicon film) 12 is subjected to anisotropic dry etching using HBr gas or Cl₂ gas, and the to-be-processed film pattern 12a is thereby formed.

In a step of FIG. 10, the slimmed stacked sidewall portions 18 are removed with a HF-based solution and phosphate-based solution. A line-and-space pattern formed by the to-be-processed film pattern 12a can be thereby obtained. In other words, a line-and-space pattern in which the space widths S are equal to each other, the line widths L are equal to each other, and the space widths S and the line widths L are equal to each other, can be obtained. The line-and-space pattern thus formed has a pitch (cycle) of 60 nm (space width S=30 nm, line width L=30 nm), which is a half of the pitch (cycle, 120 nm) of the photoresist pattern shown in FIG. 1.

According to the present embodiment, as described above, the stacked sidewall portion 18 in which the sidewall portions 16a and the sidewall portions 17a are stacked, is formed on each of both the side surfaces, of each of the core portions 13a, the core portions 13a are removed, and the sidewall portions 16a and the sidewall portions 17a are retreated at desired retreat amounts, respectively, to slim the stacked sidewall portions 18. For this reason, even if the space width S1 of the space 21 is different from the space width S2 of the space 22 due to variation in dimensions of the core portions 13a and the sidewall material films 16 and 17 as shown in FIG. 7, the space width S1′ of the space 21 can be made equal to the space width S2′ of the space 22 as shown in FIG. 8 by adjusting the retreat amount of the sidewall portions 16a and the retreat amount of the sidewall portions 17a and slimming the stacked sidewall portions 18. As a result, the to-be-processed film pattern 12a having the mutually equal space widths S can be formed as shown in FIG. 10 by patterning the to-be-processed film 12 with the slimmed stacked sidewall portions 18 serving as a mask. Therefore, by employing the method described in the present embodiment, the pattern of the to-be-processed film can be formed at a desired position at a high accuracy and an excellent semiconductor device (semiconductor integrated circuit device or the like) can be obtained.

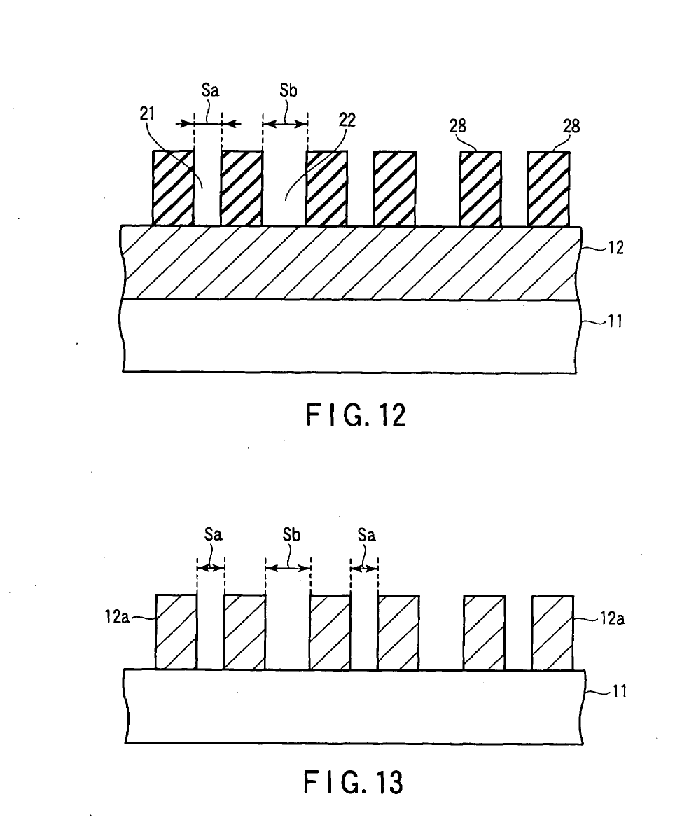

FIG. 11 to FIG. 13 are cross-sectional views illustrating a part of a method of manufacturing a semiconductor device according to a comparative example of the embodiment of the present invention. In a comparative example, single-layer sidewall portions 28 are formed on side surfaces of the core portion 13a as shown in FIG. 11. After that, the core portion 13a is removed in a step of FIG. 12. If the dimensions of the core portion 13a are off the target values, a space width Sa of the space 21 and a space width Sb of the space 22 do not become equal to each other. In this case, the space width of the space 21 and the space width of the space 22 cannot be adjusted to be equal to each other since the sidewall portions 28 have a single-layer structure, in the comparative example. For this reason, the space width Sa and the space width Sb cannot be made equal to each other in the to-be-processed film pattern 12a formed with the sidewall portion 28 serving as an etching mask, as shown in FIG. 13. In the present embodiment, such a problem can be solved effectively in the above-described method.

In the above-described embodiment, the to-be-processed film pattern 12a is formed by slimming the stacked sidewall portions 18 and etching the to-be-processed film 12 with the slimmed stacked sidewall portions 18 serving as a mask, but the to-be-processed film pattern 12a may be formed in a method described in the following modified example. In the present modified example, after the stacked sidewall portions 18 are formed in the step of FIG. 7, the to-be-processed film 12 is etched while slimming the stacked sidewall portions 18. In other words, the to-be-processed film 12 is etched while retreating the sidewall portions 16a and the sidewall portions 17a at desired retreat amounts, respectively. Slimming the stacked sidewall portions 18 and etching the to-be-processed film 12 can be executed in the same step by appropriately adjusting the etching conditions (type and flow rate of the etching gas, plasma conditions and the like). In this method, too, the to-be-processed film pattern 12a having the mutually equal space widths S can be formed as shown in FIG. 10 and the same advantage as that of the above-described embodiment can be obtained.

In addition, in the above-described embodiment, after the first sidewall portions 16a are formed in the step of FIG. 4, the second sidewall portions 17a are formed in the step of FIG. 6 and the stacked sidewall portions 18 are thereby formed. However, the stacked sidewall portions may be formed in a method described in the following modified example. In the present modified example, after the core portions 13a are formed in the step of FIG. 2, the first sidewall material film (silicon oxide film) is formed on the entire surface and the second sidewall material film (silicon nitride film) is further formed on the entire surface. In other words, the to-be-processed film 12 and the core portions 13a are covered with a stacked sidewall material film of the first sidewall material film and the second sidewall material film. After that, the stacked sidewall portions in which the first sidewall portions and the second sidewall portions are stacked are formed on both side surfaces of the core portions 13a by subjecting the stacked sidewall material film to anisotropic etching. The subsequent basic steps are the same as the steps shown in FIG. 7 to FIG. 10. In this method, too, the to-be-processed film pattern having the mutually equal space widths can be formed similarly to the above-described embodiment, and the same advantage as the above-described embodiment can be obtained.

In the above-described embodiment, a silicon oxide film is used for the first sidewall portions 16a and a silicon nitride film is used for the second sidewall portions 17a. However, the first sidewall portions 16a and the second sidewall portions 17a are not limited to those films. If the retreat amount of the first sidewall portions 16a and the retreat amount of the second sidewall portions 17a can be exactly controlled by varying the ratio of the etching rate of the first sidewall portions and the etching rate of the second sidewall portions, various films can be used for the first sidewall portions and the second sidewall portions. Generally, different types of films are used for the first sidewall portions and the second sidewall portions. In the above-described embodiment, the dimensions of the spaces, the film thicknesses of the sidewall portions and the like are controlled by slimming both the first sidewall portions 16a and the second sidewall portions 17a. However, the dimensions can also be controlled by slimming either of the first sidewall portions 16a and the second sidewall portions 17a.

In addition, in the above-described embodiment, both the first sidewall portions 16a and the second sidewall portions 17a are slimmed after removing the core portions 13a. However, the dimensions may be adjusted by executing the slimming before the removal of the core portions 13a. In other words, the thickness of the first sidewall portions 16a may be preliminarily slimmed and adjusted in the step of FIG. 4 and the thickness of the second sidewall portions 17a may be preliminarily slimmed and adjusted in the step of FIG. 6.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
forming a plurality of core portions arranged in a predetermined direction, on a to-be-processed film;
forming a stacked sidewall portion in which a first sidewall portion and a second sidewall portion are stacked in that order, on each of side surfaces, of each of the core portions;
removing the core portions to form a structure having a first space between the adjacent first sidewall portions and a second space between the adjacent second sidewall portions; and
retreating at least one of the first sidewall portion and the second sidewall portion by a desired retreat amount to slim the stacked sidewall portion, after removing the core portions.

2. The method of claim 1, further comprising etching the to-be-processed film by using the slimmed stacked sidewall portion as a mask.

3. The method of claim 1, wherein slimming the stacked sidewall portion includes etching the to-be-processed film while slimming the stacked sidewall portion.

4. The method of claim 1, wherein forming the stacked sidewall portion includes:
forming a first sidewall material film which covers the to-be-processed film and the core portions;
subjecting the first sidewall material film to anisotropic etching to form the first sidewall portions on the respective side surfaces of each of the core portions;
forming a second sidewall material film which covers the to-be-processed film, the core portions and the first sidewall portions; and
subjecting the second sidewall material film to anisotropic etching to form the second sidewall portions on the respective side surfaces of each of the core portions with the first sidewall portions interposed therebetween.

5. The method of claim 1, wherein the retreat amount of the first sidewall portion and the retreat amount of the second sidewall portion are adjusted based on a space width of the first space and a space width of the second space.

6. The method of claim 1, wherein forming the plurality of core portions includes:
forming a photoresist pattern on a core film;
slimming the photoresist pattern; and
etching the core film by using the slimmed photoresist pattern as a mask.

7. The method of claim 1, wherein forming the plurality of core portions includes:
forming a photoresist pattern on a core film;
etching the core film by using the photoresist pattern as a mask to form a preliminary core portion; and
slimming the preliminary core portion.

8. The method of claim 1, wherein the plurality of core portions are arranged at the same pitch.

9. The method of claim 1, wherein slimming the stacked sidewall portion is executed such that the retreat amount of the first sidewall portion becomes greater than the retreat amount of the second sidewall portion when a width of the first space is smaller than a width of the second space.

10. The method of claim 1, wherein slimming the stacked sidewall portion is executed such that the retreat amount of the second sidewall portion becomes greater than the retreat amount of the first sidewall portion when a width of the second space is smaller than a width of the first space.

11. The method of claim 1, wherein by slimming the stacked sidewall portion, widths of the first and second spaces are corrected and the corrected widths of the first and second spaces are equal to each other.

12. The method of claim 11, wherein a width of the slimmed stacked sidewall portion is equal to the corrected widths of the first and second spaces.

13. The method of claim 1, wherein slimming the stacked sidewall portion is executed by dry etching.

14. The method of claim 1, wherein the first sidewall portion and the second sidewall portion are formed of materials having etching rates different from each other.

15. The method of claim 1, wherein the first sidewall portion and the second sidewall portion are formed of different types of materials.
